(19) United States
(12) Patent Application Publication
(10) Pub. No.: US 2004/0163848 A1
(43) Pub. Date: Aug. 26, 2004

(54) Printed wiring board and printed wiring board manufacturing method

(75) Inventors: Eiji Takagi, Nagano (JP); Yuichi Kojima, Nagano (JP)

Correspondence Address: SUGHRUE MION, PLLC, 2100 PENNSYLVANIA AVENUE, N.W., SUITE 800, WASHINGTON, DC, 20037, US

(73) Assignee: SEIKO EPSON CORPORATION

(21) Appl. No.: 10/727,992

(22) Filed: Dec. 5, 2003

(30) Foreign Application Priority Data
Dec. 6, 2002 (JP) P2002-355644

(51) Int. Cl. H05K 1/00; H05K 1/11

(52) U.S. Cl. 174/262; 29/830; 29/846; 174/250

(57) ABSTRACT

To manufacture a printed wiring board, the positions and shapes of several slits to satisfy UL796 standard, etc., formed in a ground or power supply plane are determined so that each slit is formed in a section corresponding to a ground guard in a portion containing a signal line and a signal line gap.

The present application is based on Japanese Patent Application No. 2002-355644, which is incorporated herein by reference.

### BACKGROUND OF THE INVENTION

1. Field of the Invention

This invention relates to a printed wiring board and a printed wiring board manufacturing method.

2. Description of the Related Art

One of the safety standards of printed wiring boards is a safety standard called UL796 standard created by Underwriter's Laboratory of a nonprofit organization headquartered in Northbrook, Ill., USA.

If certification of manufacturing printed wiring boards satisfying the UL796 standard, which will be hereinafter referred to as UL certification, is obtained, it is much advantageous for selling products (particularly in USA). Thus, most of the manufacturers of printed wiring boards obtain UL certification by submitting a printed wiring board formed with a test pattern to an institute certificated in UL or UL CAP (hereinafter, represented as UL, etc.,).

Although a detailed description is not given, the printed wiring board submitted by the manufacturer of the printed wiring board to UL, etc., to obtain UL certification is formed with a conductor pattern defining the maximum diameter of conductor pattern with no hole formed on printed wiring board manufactured by the manufacturer after obtaining UL certification, which will be hereinafter referred to as maximum conductor diameter test pattern. To manufacture a printed wiring board different in specifications from the printed wiring board submitted to obtain UL certification after UL certification is obtained (to enlarge the maximum diameter of the conductor pattern with no hole formed on the printed wiring board), the manufacturer must submit a new printed wiring board to UL, etc., and take a retest.

The retest may take nearly six months. Thus, to manufacture a printed wiring board including a ground or power supply plane containing a large ground or power supply pattern, the manufacturer obtaining UL certification forms slits (openings) shaped like “GND” in various places on the ground or power supply pattern as shown in FIG. 4 as an example so as to prevent the maximum diameter of the conductor pattern with no hole existing on the ground pattern from exceeding the diameter of the maximum conductor diameter test pattern formed on the printed wiring board submitted to obtain UL certification, which will be hereinafter referred to as certification maximum diameter.

If slits are formed in various places on the ground or power supply pattern as mentioned above, the printed wiring board can satisfy the UL796 standard.

Hitherto, however, the position and shape of each silt formed in the ground or power supply pattern have been determined for the purpose of only setting the maximum diameter of the conductor pattern with no hole existing on the printed wiring board to the certification maximum diameter or less (satisfying the condition concerning the maximum conductor area, of the UL796 standard).

Thus, a printed wiring board degraded in the function as a return path of a ground or power supply pattern (a printed wiring board with insufficient suppression of EMI noise and large waveform distortion of signal) because of the slits formed in the ground or power supply pattern is often manufactured. Consequently, a circuit board manufactured using the printed wiring board does not demonstrate performance as designed.

### SUMMARY OF THE INVENTION

It is an object of the invention to provide a printed wiring board having one or more slits to satisfy UL796 standard, etc., formed in a ground or power supply plane and with no or little performance degradation caused by the presence of each slit.

It is another object of the invention to provide a printed wiring board manufacturing method capable of manufacturing a printed wiring board having one or more slits to satisfy UL796 standard, etc., formed in a ground or power supply plane and with no or little performance degradation caused by the presence of each slit.

To the end, according to the invention, there is provided a printed wiring board comprising: a portion containing a signal line and a signal line gap; and at least one of a ground and a power supply plane formed with at Least one slit, wherein a shape and a position of the slit formed in the ground or power supply plane are determined so that the slit does not exist in a section opposed to the portion containing the signal line and the signal line gap.

The printed wiring board of the invention having the configuration does not have any slit in the ground or power supply plane under a signal line and thus functions as a printed wiring board satisfying the UL796 standard, etc., and with no degradation of the function as a return path of the ground pattern caused by each slit formed to satisfy the UL796 standard, etc.

To manufacture the printed wiring board of the invention, each slit may be placed in a location where the slit is not opposed to the portion containing at least one signal line and at least one signal line gap. Thus, the printed wiring board of the invention can be manufactured so that each slit exists in a location corresponding to the location where a portion containing at least one signal line and at least one signal line gap does not exist or a location corresponding to the location where a ground guard exists, for example.

According to the invention, there is provided A method for manufacturing a printed wiring board satisfying a predetermined condition (condition concerning the maximum conductor area in the UL796 standard, etc.,), and including a portion containing a signal line and a signal line gap, and at least one of a ground and a power supply plane, said method comprising: a shape and position determination step of determining the number of slits to be formed in the ground or power supply plane and the shape and the position of each slit so that the portion containing the signal line and the signal line gap does not exist in a section opposed to each slit and a predetermined condition is satisfied; and a printed wiring board manufacturing step of manufacturing a printed wiring board with the number of slits formed in the ground or power supply plane and the shape and the position of each slit matching a processing result in said shape and position determination step.

That is, the printed wiring board manufacturing method of the invention is a method capable of manufacturing the printed wiring board of the invention. Therefore, the printed wiring board manufacturing method makes it possible to manufacture a printed wiring board satisfying the UL796 standard, etc., and with no degradation of the function as a return path of the ground or power supply pattern caused by each slit formed to satisfy the UL796 standard, etc.

### BRIEF DESCRIPTION OF THE DRAWINGS

In the accompanying drawings:

FIG. 1 is a flowchart to show a procedure of processing performed to generate structure definition information at the execution time of a printed wiring board manufacturing method according to an embodiment of the invention;

FIG. 2 is a drawing to describe slit placement locations of a printed wiring board manufactured by the printed wiring board manufacturing method according to the embodiment of the invention;

FIGS. 3A and 3B are external views of the printed wiring board manufactured by the printed wiring board manufacturing method according to the embodiment of the invention; and

FIG. 4 is a schematic representation of a printed wiring board formed with slits in a related art.

### DETAILED DESCRIPTION OF THE PREFERRED EMBODIMENTS

Referring now to the accompanying drawings, there is shown a preferred embodiment of the invention.

A printed wiring board manufacturing method according to an embodiment of the invention is used to manufacture a printed wiring board satisfying UL796 standard.

To manufacture a printed wiring board by the printed wiring board manufacturing method according to the embodiment, information defining the structure of the printed wiring board, which will be hereinafter referred to as structure definition information, is generated using a computer and then the printed wiring board is actually manufactured based on the generated structure definition information.

The structure definition information generated when the printed wiring board manufacturing method is executed is information in the same format as that generated at the time of working generally performed to manufacture printed wiring boards. The working performed to actually manufacture the printed wiring board based on the structure definition information is also the same as that generally performed to manufacture printed wiring boards.

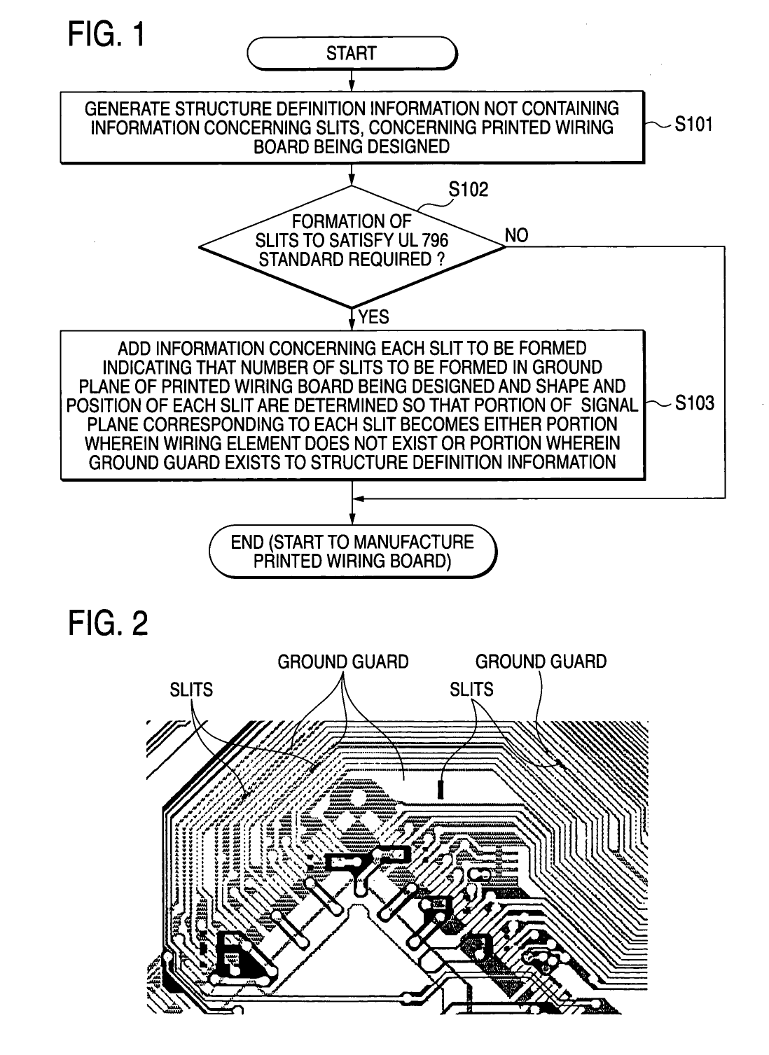

However, in the printed wiring board manufacturing method, the structure definition information is generated using a computer according to a procedure shown in FIG. 1.

That is, when a printed wiring board is manufactured by the printed wiring board manufacturing method, first, structure definition information not containing information concerning slits to satisfy the UL796 standard, about the printed wiring board to be manufactured is generated (step S101). The processing performed at step S101 is similar to that generally performed at the time of printed wiring board design.

Upon completion of generating the structure definition information, whether or not the printed wiring board being designed requires formation of slits to satisfy the UL796 standard is determined based on the generated structure definition information and the certified maximum diameter (the diameter of the maximum conductor diameter test pattern formed on the printed wiring board submitted to obtain UL certification) (step S102). If the printed wiring board does not require formation of slits (NO at step S102), the processing (work) according to the procedure shown in FIG. 1 is terminated and the work of manufacturing the printed wiring board of the structure defined in the generated structure definition information is started.

On the other hand, if the printed wiring board being designed requires formation of slits to satisfy the UL796 standard (YES at step S102), in other words, if the printed wiring board includes a ground or power supply pattern of a size not satisfying the UL796 standard, information concerning each slit to be formed indicating that the number of slits to be formed in the ground or power supply plane of the printed wiring board being designed and the shape and the position of each slit are determined so that the section opposed to each slit becomes either a section wherein a wiring element does not exist or a section wherein a ground guard exists is added to the structure definition information.

In the processing at step S103, if a slit cannot be placed in the section opposed to a portion wherein a wiring element does not exist or a portion wherein a ground guard in a portion containing at least one signal line and at least one signal line gap exists (for example, if a ground guard is not provided in a portion containing at least one signal line and at least one signal line gap or if a ground guard does not exist in the proximity of the location where the slit is to be placed), the slit is placed in a portion opposed to a portion wherein a power supply line in a portion containing at least one signal line and at least one signal line gap or a signal line for transmitting a signal of a predetermined frequency (for example, 20 MHz) or less exists.

In the printed wiring board manufacturing method according to the embodiment, a printed wiring board is actually manufactured based on the structure definition information to which the information concerning each slit is thus added.

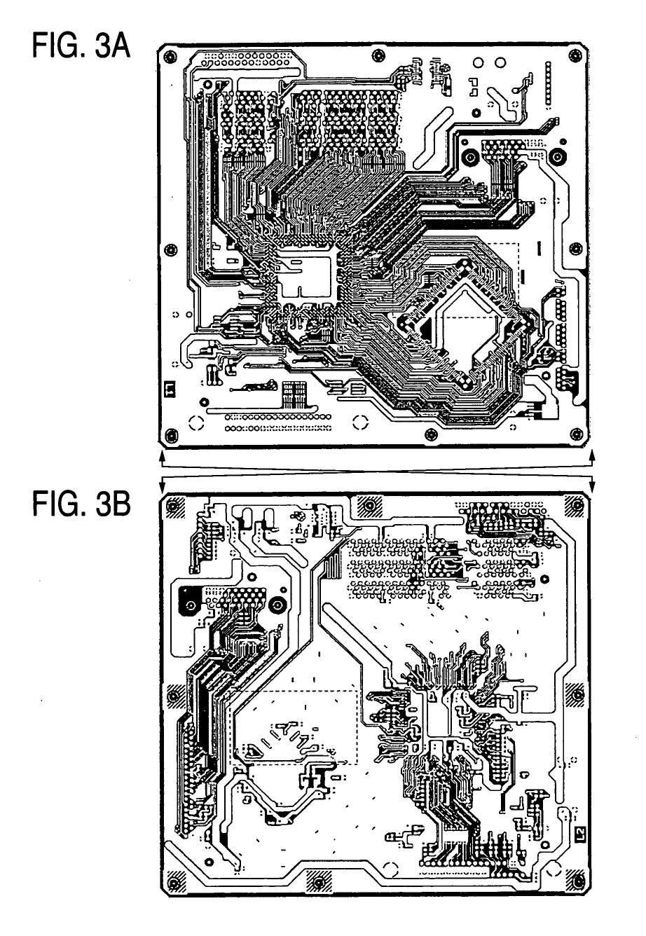

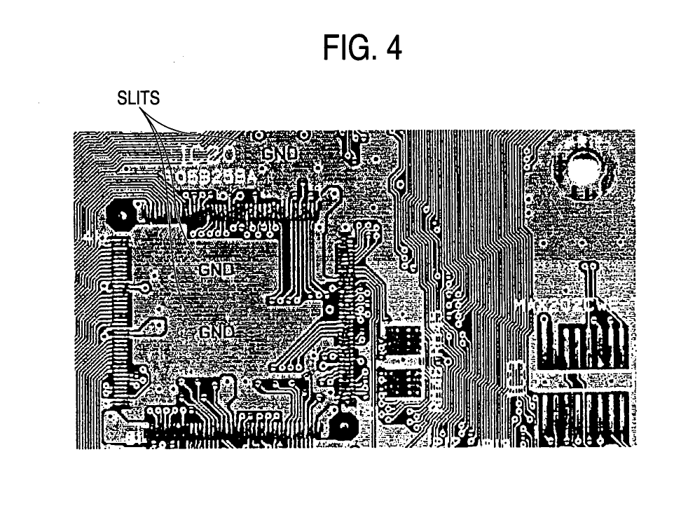

To sum up, when a printed wiring board is manufactured by the printed wiring board manufacturing method according to the embodiment, the structure definition information not containing the information concerning each slit is changed to information indicating that a slit is formed in a ground plane in the form as shown in FIG. 2 and then manufacturing a printed wiring board based on the provided structure definition information is actually started. FIG. 2 is a drawing of viewing a part of a printed wiring board for a main controller of a laser beam printer having a portion containing at least one signal line and at least one signal line gap and a ground plane shown in FIGS. 3A and 3B (part surrounded by the dotted line frame in the figure), actually manufactured by the printed wiring board manufacturing method according to the embodiment from the ground plane side.

As seen in FIG. 2 (and FIGS. 3A and 3B), the printed wiring board manufactured by the printed wiring board manufacturing method according to the embodiment is a printed wiring board wherein each slit to satisfy the UL796 standard is formed in the ground plane in such a manner that the slit does not impair the function as a return path of a signal line, of the ground plane.

Therefore, the printed wiring board manufacturing method makes it possible to manufacture a printed wiring board with no or little performance degradation caused by the presence of each slit. Consequently, a circuit board or device excellent in performance can be provided.

<Modification>

Various modifications of the described printed wiring board manufacturing method can be made as required. For example, in the described printed wiring board manufacturing method, the slit formation positions and the shape of each slit are determined using a computer, but maybe determined manually by a designer.

What is claimed is:

1. A printed wiring board comprising:
a portion containing a signal line and a signal line gap; and
at least one of a ground and a power supply plane formed with at least one slit,
wherein a shape and a position of the slit formed in the ground or power supply plane are determined so that the slit does not exist in a section opposed to the portion containing the signal line and the signal line gap.

2. A printed wiring board according to claim 1, wherein the portion containing the signal line and the signal line gap is a plane having one or more ground guards, and the shape and the position of at least one of the slits formed in the ground or power supply plane are determined so that the slit exists in the section opposed to the ground guard.

3. A printed wiring board according to claim, wherein the slit is a slit formed to satisfy a condition concerning a maximum conductor area in UL796 standard.

4. A method for manufacturing a printed wiring board comprising a portion containing a signal line and a signal line gap, and at least one of a ground and a power supply plane, said method comprising:
a shape and position determination step of determining the number of slits to be formed in the ground or power supply plane and the shape and the position of each slit so that the portion containing the signal line and the signal line gap does not exist in a section opposed to each slit and a predetermined condition is satisfied; and
a printed wiring board manufacturing step of manufacturing a printed wiring board with the number of slits formed in the ground or power supply plane and the shape and the position of each slit matching a processing result in said shape and position determination step.

5. A printed wiring board manufacturing method according to claim 4, wherein in said shape and position determination step, the shape and the position of each slit are determined so that the slit is opposed to either a section wherein a portion containing the signal line and the signal line gap exists or a section wherein a ground guard exists.

6. A printed wiring board manufacturing method according to claim 4, wherein in said shape and position determination step, the shape and the position of each slit are determined so that the slit is opposed to any of a section wherein a wiring element does not exist, a section wherein a ground guard exists, or a section wherein a power supply line or a signal line for transmitting a signal of a predetermined frequency or less exists.

7. A printed wiring board manufacturing method according to claim 4, wherein the predetermined condition is a condition concerning a maximum conductor area in UL796 standard.
